(19) United States
(12) Patent Application Publication
(10) Pub. No.: US 2026/0171128 A1
(43) Pub. Date: Jun. 18, 2026

(54) DELAY CIRCUIT AND MEMORY DEVICE INCLUDING THE SAME

(71) Applicant: SK hynix Inc., Gyeonggi-do (KR)

(72) Inventors: Kwang Soo KIM, Gyeonggi-do (KR); Chang Hyun LEE, Gyeonggi-do (KR); Byeong Chan CHOI, Gyeonggi-do (KR); Jong Seok HAN, Gyeonggi-do (KR)

(21) Appl. No.: 19/253,979

(22) Filed: Jun. 30, 2025

(30) Foreign Application Priority Data
Dec. 12, 2024 (KR) 10-2024-0184437

(51) Int. Cl. G11C 7/22; G11C 7/08; G11C 7/12; H03K 19/017

(52) U.S. Cl. CPC G11C 7/222; G11C 7/08; G11C 7/12; H03K 19/01742

(57) ABSTRACT

The embodiments of the present disclosure relate to a delay circuit and a memory device including the delay circuit, the delay circuit including a first driver coupled between a supply terminal of a first voltage and a compensation control terminal and configured to drive the compensation control terminal to a level of the first voltage based on an input signal; and a second driver coupled between a supply terminal of a second voltage and the compensation control terminal and configured to drive the compensation control terminal to a level of the second voltage based on the input signal and adjust, based on a control signal depending on parameters, a deactivation point in time of the compensation control signal.

### CROSS-REFERENCE TO RELATED APPLICATION(S)

This application claims priority under 35 U.S.C. § 119 to Korean Patent Application No. 10-2024-0184437, filed on Dec. 12, 2024, the disclosure of which is incorporated herein by reference in its entirety.

### BACKGROUND

### 1. Field

Various embodiments of the present disclosure relate to a semiconductor design technique, and more particularly, to a delay circuit that supports a mismatch compensation operation, and a memory device including the delay circuit.

### 2. Description of the Related Art

A memory device includes a bit line sense amplifier (BLSA) as an amplifier circuit for amplifying data.

FIG. 1 is a circuit diagram illustrating a bit line sense amplifier 100 according to a prior art.

Referring to FIG. 1, the bit line sense amplifier 100 includes a cross-coupled latch between a first bit line BLT and a second bit line BLB. The bit line sense amplifier 100 includes a first inverter 110 and a second inverter 120. A first memory cell CELL11 may be coupled to the first bit line BLT and a first word line WL0, and a second memory cell CELL12 may be coupled to the second bit line BLB and a second word line WL1.

Before the bit line sense amplifier 100 performs a sense and amplification operation, the first bit line BLT and the second bit line BLB may be precharged to the same voltage level. When the first word line WL0 is activated, a charge sharing operation is performed in which data stored in a capacitor C11 flows into the first bit line BLT through a cell transistor T11 of the first memory cell CELL11 coupled to the first word line WL0. By the charge sharing operation, a voltage level of the first bit line BLT becomes higher or lower than a precharge voltage level depending on a logic value of the data. In this case, the second bit line BLB maintains the precharge voltage level as it is.

After the charge sharing operation, the bit line sense amplifier 100 may be activated as a pull-up voltage is supplied to a pull-up power line RTO of the bit line sense amplifier 100 and a pull-down voltage is supplied to a pull-down power line SB of the bit line sense amplifier 100. The bit line sense amplifier 100 senses a potential difference between the first bit line BLT and the second bit line BLB. The bit line sense amplifier 100 amplifies a bit line having a higher potential among the first bit line BLT and the second bit line BLB to a higher level and amplifies a bit line having a lower potential among the first bit line BLT and the second bit line BLB to a lower level.

A minimum potential difference for the bit line sense amplifier 100 to sense the potential difference between the first bit line BLT and the second bit line BLB is referred to as an “offset voltage”. When the potential difference between the first bit line BLT and the second bit line BLB is less than the offset voltage, the bit line sense amplifier 100 may not accurately perform the sense and amplification operation. The offset voltage is related to a mismatch between the inverters 110 and 120. Because it is difficult to manufacture PMOS transistors 111 and 121 and NMOS transistors 112 and 122 included in the inverters 110 and 120 identically in terms of process, the mismatch occurs between the inverters 110 and 120.

Therefore, a technology for compensating for the mismatch occurring in the bit line sense amplifier 100 is required.

### SUMMARY

Various embodiments of the present disclosure are directed to a delay circuit capable of performing a mismatch compensation operation for an optimal time depending on an operating environment and a memory device including the delay circuit.

In accordance with an embodiment of the present disclosure, a delay circuit may include a first driver coupled between a supply terminal of a first voltage and a compensation control terminal and configured to drive the compensation control terminal to a level of the first voltage based on an input signal; and a second driver coupled between a supply terminal of a second voltage and the compensation control terminal and configured to drive the compensation control terminal to a level of the second voltage based on the input signal and adjust, based on a control signal depending on parameters, a deactivation point in time of the compensation control signal.

In accordance with an embodiment of the present disclosure, a delay circuit may include a pull-up driver operating according to an input signal and coupled between a supply terminal of a high voltage and a compensation control terminal; a pull-down driver operating according to the input signal and coupled between a supply terminal of a low voltage and a coupling node; and a compensation driver operating according to a voltage level of a single control signal and coupled between the coupling node and the compensation control terminal.

In accordance with an embodiment of the present disclosure, a memory device may include a sense amplification circuit configured to sense and amplify data loaded on a pair of bit lines; a delay circuit configured to adjust a deactivation point in time of a compensation control signal based on an input signal and a control signal depending on parameters; and a compensation circuit configured to differentially compensate for a mismatch of the sense amplification circuit based on the compensation control signal.

### BRIEF DESCRIPTION OF THE DRAWINGS

FIG. 1 is a circuit diagram illustrating a bit line sense amplifier according to a prior art.

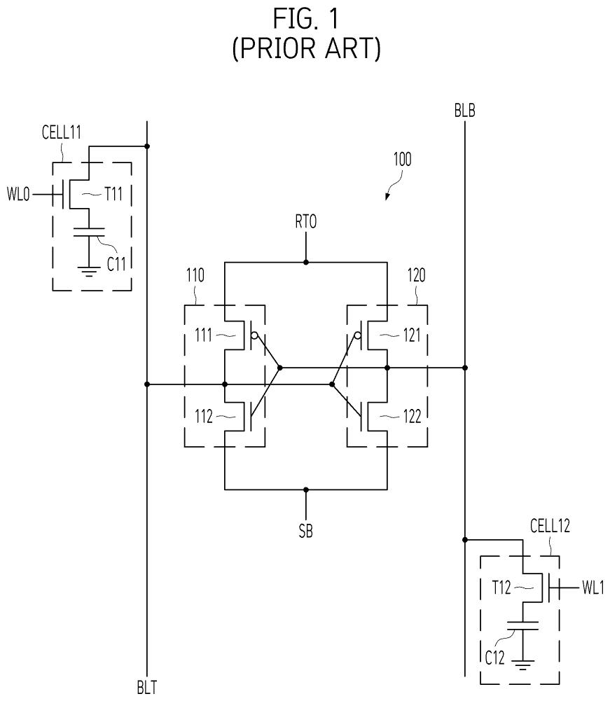

FIG. 2 is a block diagram illustrating a memory device in accordance with an embodiment of the present disclosure.

FIG. 3 is a circuit diagram illustrating a delay circuit illustrated in FIG. 2.

FIG. 4 is a circuit diagram illustrating a mismatch compensation sense amplification circuit illustrated in FIG. 2.

FIG. 5 is a timing diagram during an operation of a memory device in accordance with an embodiment of the present disclosure.

FIG. 6 is a graph for describing a relationship between a control signal and parameters described in FIG. 5.

### DETAILED DESCRIPTION

Various embodiments of the present disclosure are described below with reference to the accompanying drawings, in order to describe in detail the embodiments of the present disclosure so that those with ordinary skill in art to which the present disclosure pertains may easily carry out the technical spirit of the present disclosure.

It will be understood that when an element is referred to as being “connected to” or “coupled to” another element, the element may be directly connected to or coupled to the another element, or electrically connected to or coupled to the another element with one or more elements interposed therebetween. In addition, it will also be understood that the terms “comprises,” “comprising,” “includes,” and “including” when used in this specification do not preclude the presence of one or more other elements, but may further include or have the one or more other elements, unless otherwise mentioned. In the description throughout the present disclosure, some components are described in singular forms, but the present disclosure is not limited thereto, and it will be understood that the components may be formed in plural.

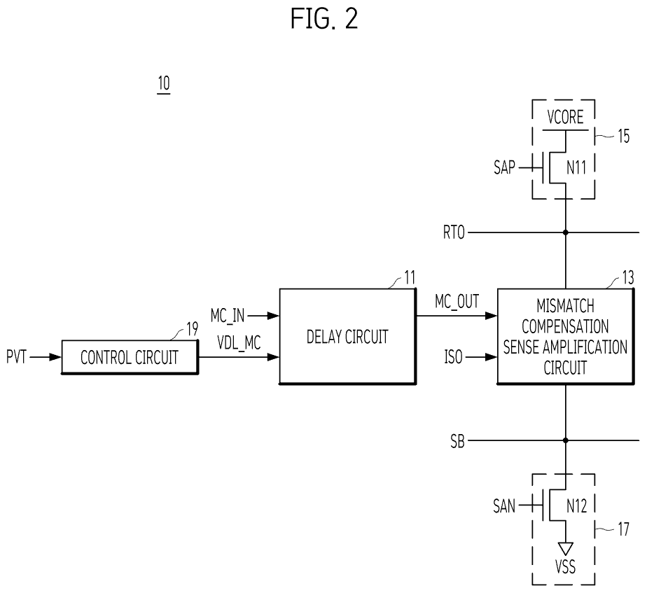

FIG. 2 is a block diagram illustrating a memory device 10 in accordance with an embodiment of the present disclosure.

Referring to FIG. 2, the memory device 10 may include a delay circuit 11, a mismatch compensation sense amplification circuit 13, a high voltage supply circuit 15, a low voltage supply circuit 17, and a control circuit 19.

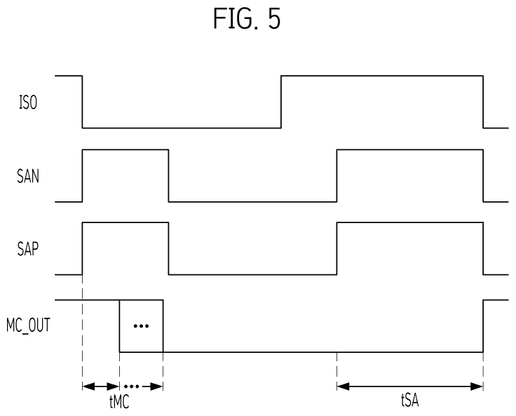

The delay circuit 11 may generate a compensation control signal MC_OUT based on an input signal MC_IN and a control signal VDL_MC. For example, the delay circuit 11 may activate the compensation control signal MC_OUT based on the input signal MC_IN and flexibly adjust a deactivation point in time of the compensation control signal MC_OUT based on the control signal VDL_MC corresponding to parameters. That is, the compensation control signal MC_OUT may be deactivated after a delay amount of compensation time tMC from when the input signal MC_IN is deactivated. The compensation time tMC may be adjusted according to the parameters, which will be described with reference to FIG. 5. The parameters represented by the control signal VDL_MC may correspond to at least one of process variation, voltage variation and temperature variation related to at least one of the delay circuit 11, the mismatch compensation sense amplification circuit 13, the high voltage supply circuit 15 and the low voltage supply circuit 17.

The mismatch compensation sense amplification circuit 13 may perform a mismatch compensation operation and a sense amplification operation based on the compensation control signal MC_OUT and a coupling control signal ISO. As technology shrinks, an offset of the mismatch compensation sense amplification circuit 13 tends to increase. The mismatch compensation sense amplification circuit 13 may compensate for the offset according to the mismatch compensation operation.

The high voltage supply circuit 15 may supply a high voltage VCORE to a pull-up power line RTO based on a first supply control signal SAP. For example, the high voltage supply circuit 15 may include an NMOS transistor N11. The NMOS transistor N11 may have source and drain terminals coupled between a supply terminal of the high voltage VCORE and the pull-up power line RTO and a gate terminal receiving the first supply control signal SAP.

The low voltage supply circuit 17 may supply a low voltage VSS to a pull-down power line SB based on a second supply control signal SAN. For example, the low voltage supply circuit 17 may include an NMOS transistor N12. The NMOS transistor N12 may have source and drain terminals coupled between the pull-down power line SB and a supply terminal of the low voltage VSS and a gate terminal receiving the second supply control signal SAN.

The control circuit 19 may generate the control signal VDL_MC depending on the parameters, based on a control information signal PVT. The control information signal PVT may include at least one of a first information signal corresponding to the process variation, a second information signal corresponding to the voltage variation and a third information signal corresponding to the temperature variation.

The process variation may refer to process distribution of at least one of the delay circuit 11, the mismatch compensation sense amplification circuit 13, the high voltage supply circuit 15 and the low voltage supply circuit 17. The voltage variation may refer to voltage distribution of at least one of voltages applied to the delay circuit 11, for example, a high voltage VDL and a low voltage VSS1, which are to be described below, the high voltage VCORE applied to the high voltage supply circuit 15 and the low voltage VSS applied to the low voltage supply circuit 17. The temperature variation may refer to temperature distribution of at least one of the delay circuit 11, the mismatch compensation sense amplification circuit 13, the high voltage supply circuit 15 and the low voltage supply circuit 17. The process variation, the voltage variation and the temperature variation may be monitored during a test mode of the memory device 10, and the control information signal PVT may be set based on at least one of the process variation, the voltage variation and the temperature variation during the test mode.

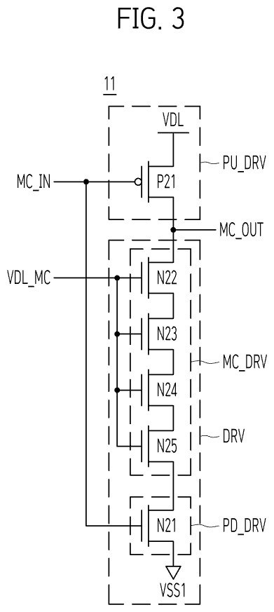

FIG. 3 is a circuit diagram illustrating the delay circuit 11 illustrated in FIG. 2.

Referring to FIG. 3, the delay circuit 11 may include a first driver PU_DRV and a second driver DRV.

The first driver PU_DRV, which is a pull-up driver, may pull-up drive an output terminal of the delay circuit 11 to the level of high voltage VDL based on the input signal MC_IN. The delay circuit 11 may output the compensation control signal MC_OUT through the output terminal. Hereinafter, the output terminal of the compensation control signal MC_OUT is defined as a compensation control terminal. For example, the first driver PU_DRV may include a PMOS transistor P21. The PMOS transistor P21 may have source and drain terminals coupled between the high voltage VDL and the compensation control terminal and a gate terminal receiving the input signal MC_IN.

The second driver DRV may pull-down drive the compensation control terminal to the level of the low voltage VSS1 based on the input signal MC_IN. In particular, the second driver DRV may flexibly adjust the deactivation point in time of the compensation control signal MC_OUT based on the control signal VDL_MC depending on the parameters. For example, the second driver DRV may include a compensation driver MC_DRV and a pull-down driver PD_DRV coupled in series between the compensation control terminal and a supply terminal of the low voltage VSS1.

The compensation driver MC_DRV may be coupled between the compensation control terminal and a coupling node. The compensation driver MC_DRV may be controlled according to the control signal VDL_MC. For example, the compensation driver MC_DRV may flexibly adjust, based on the control signal VDL_MC depending on the parameters, a resistance value between the compensation control terminal and the supply terminal of the low voltage VSS1. As the voltage level of the control signal VDL_MC becomes higher, a driving force of the compensation driver MC_DRV becomes stronger and the resistance value becomes lesser. As the voltage level of the control signal VDL_MC becomes lower, the driving force of the compensation driver MC_DRV becomes weaker and the resistance value becomes greater.

For example, the compensation driver MC_DRV may include first to fourth NMOS transistors N22, N23, N24 and N25 coupled in. The first NMOS transistor N22 may have source and drain terminals coupled between the compensation control terminal and the second NMOS transistor N23 and a gate terminal receiving the control signal VDL_MC. The second NMOS transistor N23 may have source and drain terminals coupled between the first NMOS transistor N22 and the third NMOS transistor N24 and a gate terminal receiving the control signal VDL_MC. The third NMOS transistor N24 may have source and drain terminals coupled between the second NMOS transistor N23 and the fourth NMOS transistor N25 and a gate terminal receiving the control signal VDL_MC. The fourth NMOS transistor N25 may have source and drain terminals coupled between the third NMOS transistor N24 and the coupling node and a gate terminal receiving the control signal VDL_MC. In an embodiment, it is described that the compensation driver MC_DRV includes the first to fourth NMOS transistors N22, N23, N24 and N25 coupled in series, but the embodiments are not necessarily limited thereto, and the compensation driver MC_DRV may include at least one NMOS transistor coupled in series. As a quantity of NMOS transistors included in the compensation driver MC_DRV becomes greater, the delay amount of the compensation time tMC may become greater within a range controlled by the voltage level of the control signal VDL_MC. The quantity of the NMOS transistors included in the compensation driver MC_DRV may be determined depending on design for the memory device 10.

In an embodiment, it is described that the compensation driver MC_DRV is coupled between the compensation control terminal and the pull-down driver PD_DRV, but the embodiments are not necessarily limited thereto, and the compensation driver MC_DRV may be coupled between the compensation control terminal and the first driver PU_DRV depending on design, that is, an activation level of the compensation control signal MC_OUT.

The pull-down driver PD_DRV may be coupled between the coupling node and the supply terminal of the low voltage VSS1. The pull-down driver PD_DRV may be controlled according to the input signal MC_IN. For example, the pull-down driver PD_DRV may pull-down drive, based on the input signal MC_IN, the compensation control terminal to the level of low voltage VSS1 through the compensation driver MC_DRV. For example, the pull-down driver PD_DRV may include an NMOS transistor N21. The NMOS transistor N21 may have source and drain terminals coupled between the coupling node and the supply terminal of the low voltage VSS1 and a gate terminal receiving the input signal MC_IN.

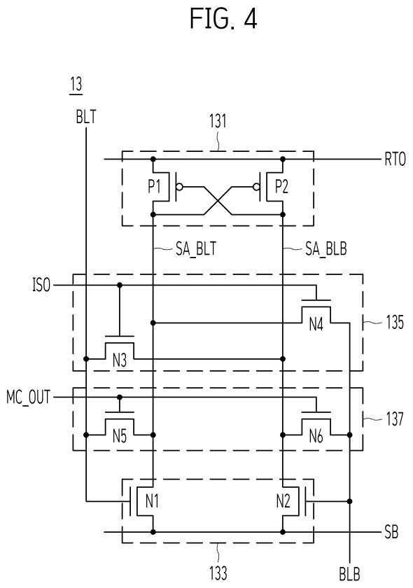

FIG. 4 is a circuit diagram illustrating the mismatch compensation sense amplification circuit 13 illustrated in FIG. 2.

Referring to FIG. 4, the mismatch compensation sense amplification circuit 13 may include a pull-up amplifier 131, a pull-down amplifier 133, a coupler 135, and a mismatch compensator 137.

The pull-up amplifier 131 may be coupled between the pull-up power line RTO and a pair of sensing bit lines SA_BLT and SA_BLB. For example, the pull-up amplifier 131 may include first and second PMOS transistors P1 and P2. The first and second PMOS transistors P1 and P2 may be cross-coupled between the pull-up power line RTO and the pair of sensing bit lines SA_BLT and SA_BLB. The first PMOS transistor P1 may have source and drain terminals coupled between the pull-up power line RTO and a first sensing bit line SA_BLT and a gate terminal coupled to a second sensing bit line SA_BLB. The first PMOS transistor P1 may drive the first sensing bit line SA_BLT to the level of high voltage VCORE supplied to the pull-up power line RTO, according to a voltage level of the second sensing bit line SA_BLB. The second PMOS transistor P2 may have source and drain terminals coupled between the pull-up power line RTO and the second sensing bit line SA_BLB and a gate terminal coupled to the first sensing bit line SA_BLT. The second PMOS transistor P2 may drive the second sensing bit line SA_BLB to the level of high voltage VCORE supplied to the pull-up power line RTO, according to a voltage level of the first sensing bit line SA_BLT.

The pull-down amplifier 133 may be coupled to a pair of bit lines BLT and BLB, the pull-down power line SB and the pair of sensing bit lines SA_BLT and SA_BLB. For example, the pull-down amplifier 133 may include first and second NMOS transistors N1 and N2. The first NMOS transistor N1 may have source and drain terminals coupled between the pull-down power line SB and the first sensing bit line SA_BLT and a gate terminal coupled to a first bit line BLT. The first NMOS transistor N1 may drive the first sensing bit line SA_BLT to the level of low voltage VSS supplied to the pull-down power line SB, according to a voltage level of the first bit line BLT. The second NMOS transistor N2 may have source and drain terminals coupled between the pull-down power line SB and the second sensing bit line SA_BLB and a gate terminal coupled to a second bit line BLB. The second NMOS transistor N2 may drive the second sensing bit line SA_BLB to the level of low voltage VSS supplied to the pull-down power line SB, according to a voltage level of the second bit line BLB.

The pull-up amplifier 131 and the pull-down amplifier 133 may correspond to one amplifier having a latch structure. The pull-up amplifier 131 and the pull-down amplifier 133 may sense and amplify data loaded on the pair of sensing bit lines SA_BLT and SA_BLB.

The coupler 135 may be coupled between the pair of bit lines BLT and BLB and the pair of sensing bit lines SA_BLT and SA_BLB. The coupler 135 may electrically isolate the pair of bit lines BLT and BLB from the pair of sensing bit lines SA_BLT and SA_BLB during a compensation period and electrically couple the pair of bit lines BLT and BLB to the pair of sensing bit lines SA_BLT and SA_BLB during a sense amplification period, based on the coupling control signal ISO. The compensation period may be an initial period in which the mismatch compensation operation is performed during an active period, and the sense amplification period may be a subsequent period in which the sense amplification operation is performed during the active period.

For example, the coupler 135 may include first and second NMOS transistors N3 and N4. The first NMOS transistor N3 may have drain and source terminals coupled between the first bit line BLT and the second sensing bit line SA_BLB and a gate terminal receiving the coupling control signal ISO. The second NMOS transistor N4 may have drain and source terminals coupled between the second bit line BLB and the first sensing bit line SA_BLT and a gate terminal receiving the coupling control signal ISO. The coupling control signal ISO may be deactivated during the compensation period and activated during the sense amplification period.

The mismatch compensator 137 may be coupled between the pair of bit lines BLT and BLB and the pair of sensing bit lines SA_BLT and SA_BLB. The mismatch compensator 137 may electrically couple the pair of bit lines BLT and BLB to the pair of sensing bit lines SA_BLT and SA_BLB during the compensation period and electrically isolate the pair of bit lines BLT and BLB from the pair of sensing bit lines SA_BLT and SA_BLB during the sense amplification period, based on the compensation control signal MC_OUT. The mismatch compensator 137 may compensate for a mismatch between the transistors P1, P2, N1 and N2 included in the pull-up amplifier 131 and the pull-down amplifier 133 by electrically coupling the pair of bit lines BLT and BLB to the pair of sensing bit lines SA_BLT and SA_BLB during the compensation period. For example, when a threshold voltage of the first NMOS transistor N1 is higher than a threshold voltage of the second NMOS transistor N2 according to the mismatch between the first NMOS transistor N1 and the second NMOS transistor N2. During the compensation period, a voltage difference between the first bit line BLT and the second bit line BLB may occur as a second current flowing through the second NMOS transistor N2 increases more than a first current flowing through the first NMOS transistor N1. The voltage difference between the first bit line BLT and the second bit line BLB may be reflected to the first NMOS transistor N1 and the second NMOS transistor N2 during the sense amplification period, so that the mismatch between the first NMOS transistor N1 and the second NMOS transistor N2 may be compensated.

For example, the mismatch compensator 137 may include first and second NMOS transistors N5 and N6. The first NMOS transistor N5 may have drain and source terminals coupled between the first bit line BLT and the first sensing bit line SA_BLT and a gate terminal receiving the compensation control signal MC_OUT. The second NMOS transistor N6 may have drain and source terminals coupled between the second bit line BLB and the second sensing bit line SA_BLB and a gate terminal receiving the compensation control signal MC_OUT. The compensation control signal MC_OUT may be activated during the compensation period and deactivated during the sense amplification period.

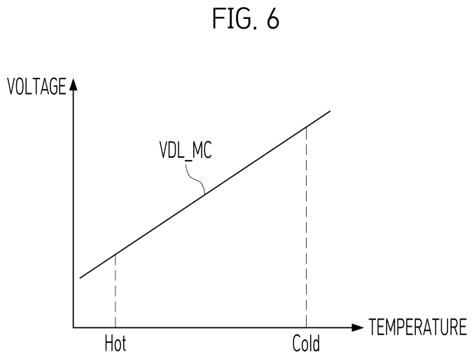

Hereinafter, an operation of the memory device 10 in accordance with an embodiment, which has the above-described configuration, is described with reference to FIGS. 5 and 6.

FIG. 5 is a timing diagram during the operation of the memory device 10 illustrated in FIG. 2.

Referring to FIG. 5, the delay circuit 11 may generate the compensation control signal MC_OUT based on the input signal MC_IN and the control signal VDL_MC. For example, the delay circuit 11 may activate the compensation control signal MC_OUT based on the input signal MC_IN and flexibly adjust the deactivation point in time of the compensation control signal MC_OUT based on the control signal VDL_MC. In particular, the delay circuit 11 may flexibly adjust the deactivation point in time of the compensation control signal MC_OUT according to the voltage level of the control signal VDL_MC, which is a single signal. The compensation driver MC_DRV included in the delay circuit 11 may flexibly adjust the resistance value reflected between the compensation control terminal and the supply terminal of the low voltage VSS1 based on the voltage level of the control signal VDL_MC depending on the parameters, thereby allowing the deactivation point in time of the compensation control signal MC_OUT to be flexibly adjusted. The parameters represented by the control signal VDL_MC may correspond to at least one of process variation, voltage variation and temperature variation related to at least one of the delay circuit 11, the mismatch compensation sense amplification circuit 13, the high voltage supply circuit 15 and the low voltage supply circuit 17.

The mismatch compensation sense amplification circuit 13 may perform the mismatch compensation operation and the sense amplification operation based on the compensation control signal MC_OUT and the coupling control signal ISO. The compensation control signal MC_OUT may be activated for the compensation time tMC that is flexibly adjusted during the compensation period and deactivated for a sense amplification time tSA corresponding to the sense amplification period. The coupling control signal ISO may be deactivated during the compensation period and activated during the sense amplification period. The mismatch compensation sense amplification circuit 13 may compensate for the offset according to the mismatch compensation operation, sense and amplify data loaded on the pair of sensing bit lines SA_BLT and SA_BLB according to the sense amplification operation.

The high voltage supply circuit 15 may supply the high voltage VCORE to the pull-up power line RTO based on the first supply control signal SAP. For example, the first supply control signal SAP may be activated during the compensation period and the sense amplification period.

The low voltage supply circuit 17 may supply the low voltage VSS to the pull-up power line SB based on the second supply control signal SAN. For example, the second supply control signal SAN may be activated during the compensation period and the sense amplification period.

FIG. 6 is a graph for describing a relationship between the control signal VDL_MC and the parameters. For example, FIG. 6 representatively illustrates a relationship between the control signal VDL_MC and the temperature variation, which corresponds to the parameters.

Referring to FIG. 6, the control signal VDL_MC may have a relatively low voltage level as the temperature is high and have a relatively high voltage level as the temperature is low. Accordingly, the deactivation point in time of the compensation control signal MC_OUT may be delayed as the control signal VDL_MC has a low voltage level and be advanced as the control signal VDL_MC has a high voltage level.

According to an embodiment of the present disclosure, it is possible to perform a mismatch compensation operation for an optimal time, that is, a flexibly adjustable compensation time tMC, depending on an operating environment.

According to an embodiment of the present disclosure, a mismatch compensation operation may be performed for an optimal time depending on an operating environment, which makes it possible to improve a sensing margin of a sense amplification circuit.

While the scope of the present disclosure has been illustrated and described with respect to specific embodiments, the disclosed embodiments are provided for the description, and not intended to be restrictive. Further, it is noted that the embodiments of the present disclosure may be achieved in various ways through substitution, change, and modification that fall within the scope of the following claims, as those skilled in the art will recognize in light of the present disclosure. The embodiments may be combined to form additional embodiments.

What is claimed is:

1. A delay circuit comprising:
a first driver coupled between a supply terminal of a first voltage and a compensation control terminal and configured to drive the compensation control terminal to a level of the first voltage based on an input signal; and
a second driver coupled between a supply terminal of a second voltage and the compensation control terminal and configured to drive the compensation control terminal to a level of the second voltage based on the input signal and adjust, based on a control signal depending on parameters, a deactivation point in time of the compensation control signal.

2. The delay circuit of claim 1, wherein the parameters correspond to at least one of process variation, voltage variation and temperature variation.

3. The delay circuit of claim 1, wherein the compensation control signal controls a mismatch compensation operation of driving, to the same voltage level, a pair of bit lines coupled to a selected memory cell before a sense operation of amplifying data loaded on the pair of bit lines.

4. The delay circuit of claim 1, wherein the second driver includes:
a compensation driver operating according to the control signal and coupled between the compensation control terminal and a coupling node; and
a pull-down driver operating according to the input signal and coupled between the coupling node and the supply terminal of the second voltage.

5. The delay circuit of claim 1, wherein the control signal is a single signal.

6. A delay circuit comprising:
a pull-up driver operating according to an input signal and coupled between a supply terminal of a high voltage and a compensation control terminal;
a pull-down driver operating according to the input signal and coupled between a supply terminal of a low voltage and a coupling node; and
a compensation driver operating according to a voltage level of a single control signal and coupled between the coupling node and the compensation control terminal.

7. The delay circuit of claim 6, wherein the compensation driver is configured to adjust, based on the control signal depending on parameters, a deactivation point in time of a compensation control signal output from the compensation control terminal.

8. The delay circuit of claim 7, wherein the parameters correspond to at least one of process variation, voltage variation and temperature variation.

9. The delay circuit of claim 7, wherein the compensation control signal controls a mismatch compensation operation of driving, to the same voltage level, a pair of bit lines coupled to a selected memory cell before a sense operation of amplifying data loaded on the pair of bit lines.

10. A memory device comprising:
a sense amplification circuit configured to sense and amplify data loaded on a pair of bit lines;
a delay circuit configured to adjust a deactivation point in time of a compensation control signal based on an input signal and a control signal depending on parameters; and
a compensation circuit configured to differentially compensate for a mismatch of the sense amplification circuit based on the compensation control signal.

11. The memory device of claim 10, wherein the parameters include at least one of process variation, voltage variation and temperature variation.

12. The memory device of claim 10, wherein the compensation control signal is a single signal.

13. The memory device of claim 10, wherein the delay circuit adjusts the deactivation point in time of the compensation control signal according to a voltage level of the control signal.

14. The memory device of claim 10, wherein the delay circuit includes:
a pull-up driver operating according to the input signal and coupled between a supply terminal of a first high voltage and a compensation control terminal; and
a driver operating according to the input signal and the control signal and coupled between a supply terminal of a first low voltage and the compensation control terminal.

15. The memory device of claim 14, wherein the driver includes:
a compensation driver operating according to the control signal and coupled between the compensation control terminal and a coupling node; and
a pull-down driver operating according to the input signal and coupled between the coupling node and the supply terminal of the first low voltage.

16. The memory device of claim 15, wherein the compensation driver is configured to adjust, based on the control signal, the deactivation point in time of the compensation control signal output from the compensation control terminal.
